(19) United States
(12) Patent Application Publication
(10) Pub. No.: US 2007/0194863 A1
(43) Pub. Date: Aug. 23, 2007

(54) FILM BULK ACOUSTIC RESONATOR AND METHOD OF MANUFACTURING SAME

(75) Inventors: Hironobu Shibata, Kanagawa-ken (JP); Masaki Sakai, Fukuoka-ken (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: KABUSHIKI KAISHA TOSHIBA, Tokyo (JP)

(21) Appl. No.: 11/627,577

(22) Filed: Jan. 26, 2007

(30) Foreign Application Priority Data
Feb. 17, 2006 (JP) 2006-041427

(51) Int. Cl. H03H 9/54

(52) U.S. Cl. 333/187

(57) ABSTRACT

A film bulk acoustic resonator includes: a substrate having; a lower electrode extending; a piezoelectric film provided on the lower electrode; an upper electrode opposed to the lower electrode and provided on the piezoelectric film; and a plurality of protrusions. The substrate has a cavity in a surface thereof. The lower electrode extends above the cavity from an upper surface of the substrate. The protrusions are provided below the lower electrode in the cavity.

### CROSS-REFERENCE TO RELATED APPLICATION

This application is based upon and claims the benefit of priority from the prior Japanese Patent Application No. 2006-041427, filed on Feb. 17, 2006; the entire contents of which are incorporated herein by reference.

### BACKGROUND OF THE INVENTION

1. Field of the Invention

This invention relates to a film bulk acoustic resonator, and more particularly to a film bulk acoustic resonator used in high frequency bands and a method of manufacturing the same

2. Background Art

In recent years, GHz or higher frequency bands are used for wireless communication systems including mobile communication devices such as mobile phones and wireless local area network (LAN) systems for rapidly transferring data between computers. A film bulk acoustic resonator (FBAR) is one of the high-frequency elements used in such wireless communication systems and other high-frequency-band electronic devices.

Conventionally, bulk (ceramic) dielectric resonators and surface acoustic wave (SAW) elements are used as resonators in the high frequency region. As compared with these resonators, an FBAR is characterized by being suited to downsizing and adaptable to even higher frequencies. Thus high-frequency filters and resonant circuits based on FBARs are being developed.

In the basic configuration of an FBAR, a piezoelectric film of aluminum nitride (AlN) or zinc oxide (ZnO) is sandwiched between a lower electrode and an upper electrode being opposed to each other. To achieve higher performance, the resonator section of the FBAR bridges a cavity. U.S. Pat. No. 6,060,818, for example, discloses a method of manufacturing an FBAR bridging a cavity by using a sacrificial material.

For example, a sacrificial film is deposited so as to fill a groove formed in a substrate. The deposited sacrificial film is planarized. A lower electrode, a piezoelectric film, and an upper electrode are successively formed so as to cover the sacrificial film. Then the sacrificial film is removed to form a cavity below the resonator section of the FBAR.

When a sacrificial film of phosphosilicate glass (PSG), for example, is planarized by chemical mechanical polishing (CMP), dishing is likely to occur in the surface subjected to CMP due to the difference in hardness between the sacrificial film and the substrate. Due to dishing, the surface of the buried sacrificial film is recessed toward the underlying substrate side. Thus a strain occurs in the resonator section formed on the dished sacrificial film. Removal of the sacrificial film for forming a cavity further increases the strain in the resonator section. This results in degrading the resonance characteristics of the FBAR. Moreover, in drying or other steps after etching the sacrificial film, the resonator section may bend due to the surface tension of water remaining in the cavity and be stuck to the bottom surface of the cavity, thereby causing a problem of disturbing resonance.

### SUMMARY OF THE INVENTION

According to an aspect of the invention, there is provided a film bulk acoustic resonator including: a substrate having a cavity in a surface thereof; a lower electrode extending above the cavity from an upper surface of the substrate; a piezoelectric film provided on the lower electrode; an upper electrode opposed to the lower electrode and provided on the piezoelectric film; and a plurality of protrusions provided below the lower electrode in the cavity.

According to other aspect of the invention, there is provided a method of manufacturing a film bulk acoustic resonator including: removing part of a substrate to form a plurality of isolated first supports and a second support surrounding the plurality of first supports in a box configuration; forming a sacrificial film and a sidewall film so as to bury, respectively, a first gap provided between each pair of the plurality of first supports and between the plurality of first supports and the second support and a second gap provided around the second support between the second support and the substrate; forming a lower electrode extending above the sacrificial film and the first supports from above the substrate; forming a piezoelectric film on a surface of the lower electrode; forming an upper electrode opposed to the lower electrode and located on the piezoelectric film; removing the sacrificial film to form a cavity below a resonator section defined by a region where the lower electrode is opposed to the upper electrode; and removing at least part in a height direction of each of the plurality of first supports in the cavity.

### BRIEF DESCRIPTION OF THE DRAWINGS

FIG. 1 is a plan view showing an example FBAR according to an embodiment of the invention.

FIG. 2 shows the A-A cross section of the FBAR shown in FIG. 1.

FIG. 3 shows the B-B cross section of the FBAR shown in FIG. 1.

FIG. 4 is a plan view showing an example method of manufacturing an FBAR according to the embodiment of the invention.

FIGS. 5A-5C show the C-C cross sections of the substrate shown in FIG. 4.

FIGS. 6 to 10 are cross-sectional views showing the example method of manufacturing the FBAR according to the embodiment of the invention.

FIG. 11 is a plan view showing the example method of manufacturing the FBAR according to the embodiment of the invention.

FIG. 12 shows the D-D cross section of the substrate shown in FIG. 11.

FIGS. 13 and 14 are cross-sectional views showing the example method of manufacturing the FBAR according to the embodiment of the invention.

FIG. 15 is a plan view showing another example FBAR according to the embodiment of the invention.

FIG. 16 is a plan view showing still another example FBAR according to the embodiment of the invention.

FIG. 17 is a plan view showing an example FBAR according to a first variation of the embodiment of the invention.

FIG. 18 shows the E-E cross section of the FBAR shown in FIG. 17.

FIG. 19 is a plan view showing an example FBAR according to a second variation of the embodiment of the invention.

FIG. 20 shows the F-F cross section of the FBAR shown in FIG. 19.

### DETAILED DESCRIPTION OF THE INVENTION

Embodiments of the invention will now be described with reference to the drawings. In the following description of the drawings, like or similar elements are marked with like or similar reference numerals. The figures are schematic, and hence it should be noted that the relationship between the thickness and the planar dimensions, the ratio of thickness of the layers and the like are different from actual ones. Therefore the specific thicknesses and dimensions should be understood in light of the following description. Furthermore, it is understood that the relationship or ratio of some dimensions may be different from each other in various figures.

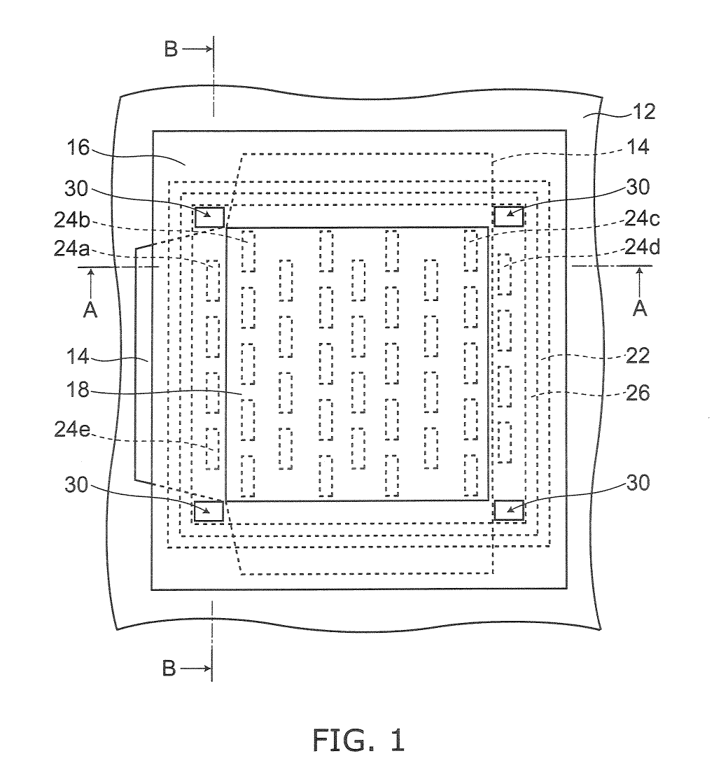

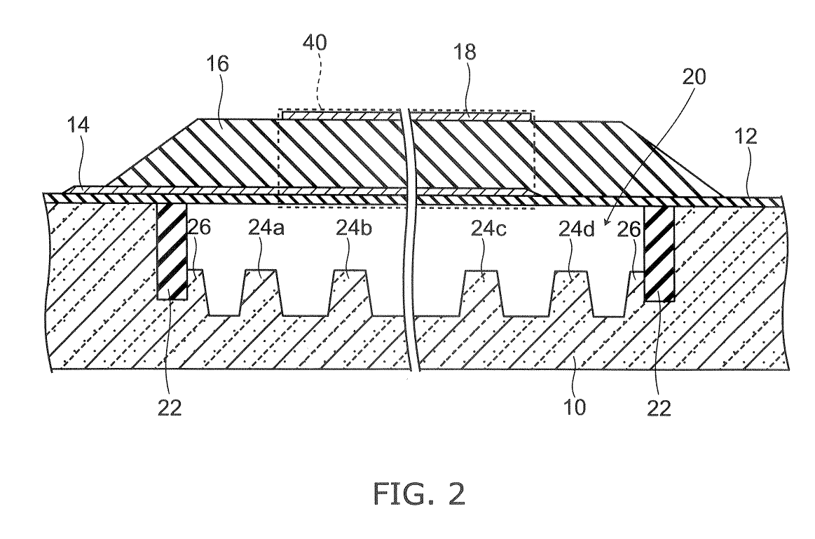

As shown in FIGS. 1 and 2, an FBAR according to the embodiment of the invention includes a substrate 10, a lower electrode 14 provided on the substrate 10, a piezoelectric film 16 provided on the lower electrode 14, and an upper electrode 18 provided on the piezoelectric film 16. The substrate 10 has a cavity 20 in its surface. The lower electrode 14 extends above the cavity 20 from the upper surface of the substrate 10. The piezoelectric film 16 covers the cavity 20 and part of the lower electrode 14. The upper electrode 18 is opposed to the lower electrode 14. In the cavity 20 below the lower electrode 14, a plurality of protrusions 24a, 24b, . . . , 24c, 24d, . .. , 24e, . . . are provided on the substrate 10 defining the cavity 20. A protection film 12 is provided between the substrate 10 and the lower electrode 14.

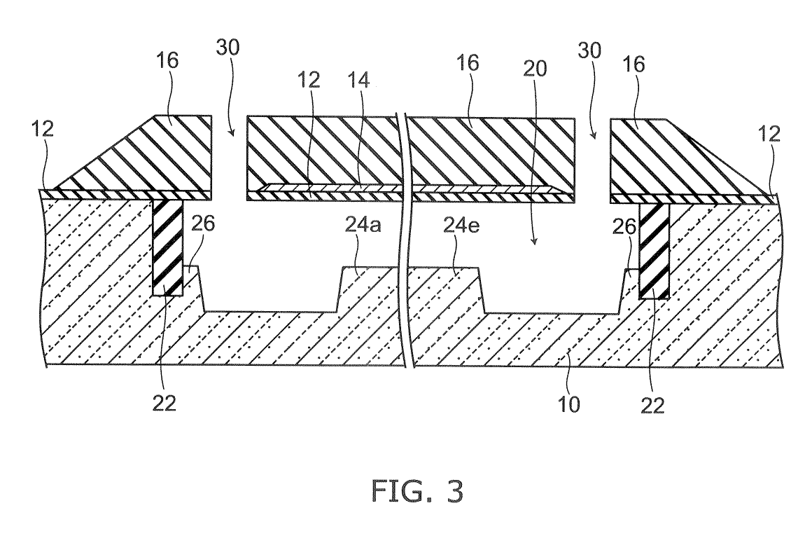

The plurality of protrusions 24a-24e, . . . are surrounded by a sidewall film 22, which is made of a material different from that of the substrate 10. A surrounding wall 26 is provided in contact with the sidewall film 22. A resonator section 40 is defined by a region above the cavity 20 where the lower and upper electrode 14, 18 are opposed to each other. As shown in FIG. 3, the piezoelectric film 16 and the protection film 12 located outside the resonator section 40 are provided with openings 30 in communication with the cavity 20 formed below the resonator section 40.

The piezoelectric film 16 of the resonator section 40 transfers a high-frequency signal due to the resonance of bulk acoustic waves excited by a high-frequency signal applied to the lower electrode 14 or the upper electrode 18. For example, a high-frequency signal in the GHz band applied to the lower electrode 14 is transferred to the upper electrode 18 through the piezoelectric film 16 of the resonator section 40. To achieve good resonance characteristics of the resonator section 40, the piezoelectric film 16 is made of an AlN film or ZnO film having good uniformity in film quality including crystal orientation and in film thickness.

The lower electrode 14 is made of a laminated metal film of aluminum (Al) and tantalum aluminum (TaAl), a high melting point metal such as molybdenum (Mo), tungsten (W), and titanium (Ti), or a metal compound containing a high melting point metal. The upper electrode 18 is made of a metal such as Al, a high melting point metal such as Mo, W, and Ti, or a metal compound containing a high melting point metal. The substrate 10 is a Si or other semiconductor substrate, for example. The protection film 12 is an insulating film made of AlN, for example. The sidewall film 22 is an insulating film made of silicon oxide (SiO₂), for example, which is a material different from that of the substrate 10.

The dimensions of the cavity 20 depend on the operating frequency and the cross-sectional structure of the FBAR. In this embodiment, each side has a length of about 100 μm to about 200 μm. The plurality of protrusions 24a-24e have a rectangular planar shape, the shorter side of which measures in the range of about 1 μm to about 10 μm. The spacing between each pair of the plurality of protrusions 24a-24e is about 10 μm or less.

In the FBAR according to the embodiment, the plurality of protrusions 24a-24e are provided on the bottom surface of the cavity 20 formed below the resonator section 40. The area of the upper surface of the plurality of protrusions 24a-24e is less than the total area of the resonator section 40. Therefore, if the resonator section 40 bends during the manufacturing process and comes into contact with the upper surface of the plurality of protrusions 24a-24e, the resonator section 40 is not stuck to the upper surface of the plurality of protrusions 24a-24e. Thus the embodiment can prevent the degradation of resonance characteristics due to the sticking of the resonator section 40 to the substrate 10.

The piezoelectric film 16 is grown on the surface where the lower electrode 14 is formed on the protection film 12. At the stepped portion between the protection film 12 and the lower electrode 14, the orientation of the piezoelectric film 16 is changed. As a result, the piezoelectric film 16 is subjected to stress concentration, which results in such problems as the degradation of piezoelectric characteristics and cracks in the piezoelectric film 16. To alleviate the influence of the stepped portion, the end of the lower electrode 14 is preferably beveled at an angle sufficiently smaller than the right angle with respect to the surface of the protection film 12.

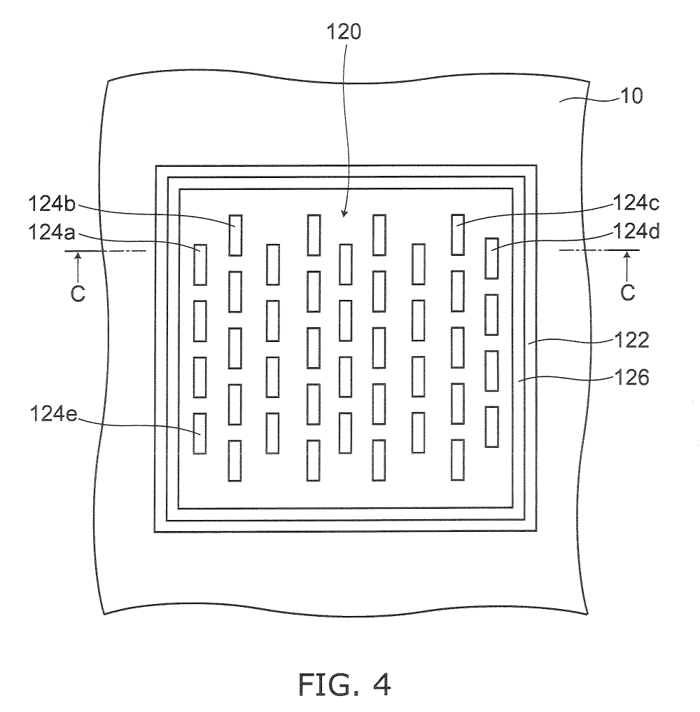

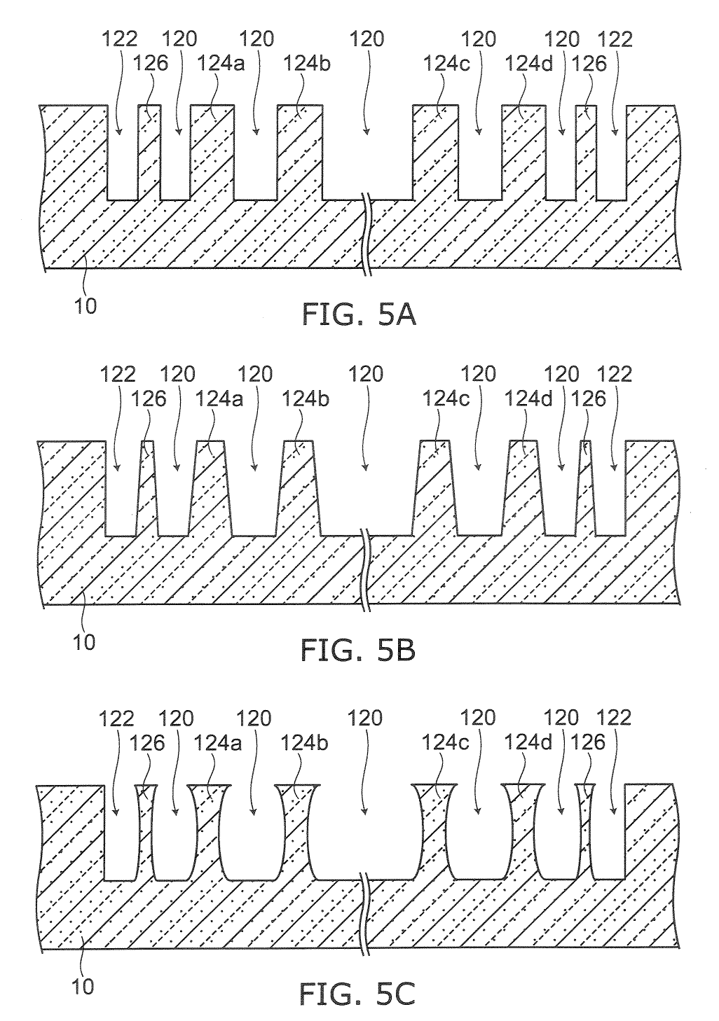

Next, a method of manufacturing an FBAR according to the embodiment is described with reference to the process plan views and cross-sectional views shown in FIGS. 4 to 14. Here, lines corresponding to lines A-A and B-B shown in FIG. 1 are depicted in the cross-sectional views used for description. (A) As shown in FIGS. 4 and 5A, part of a Si or other substrate 10 is removed by such processes as photolithography and reactive ion etching (RIE) to form a plurality of isolated first supports 124a, 124b, . . . , 124c, 124d, . . . , 124e, . . . and a second support 126 surrounding the plurality of first supports 124a-124e, . . . in a box configuration. A first gap 120 is provided between each pair of the plurality of first supports 124a-124e, . . . , each being shaped as a prism, and between the plurality of first supports 124a-124e, . . . and the second support 126. The plurality of first supports 124a-124e each have a rectangular upper surface of about 2 μm×10 μm. The spacing between the adjacent first supports 124a-124e is about 10 μm or less. Around the second support 126, a second gap 122 is provided between the second support 126 and the substrate 10. The shape of the side surface of the first and second support(s) 124a-124e, 126 is processed so that the center portion along the depth is thinned.

The first and second support(s) 124a-124d, 126 may be thinned at the upper portion along the depth as shown in FIG. 5B. Alternatively, the first and second support(s) 124a-124d, 126 may be thinned at the center portion along the depth as show in FIG. 5C.

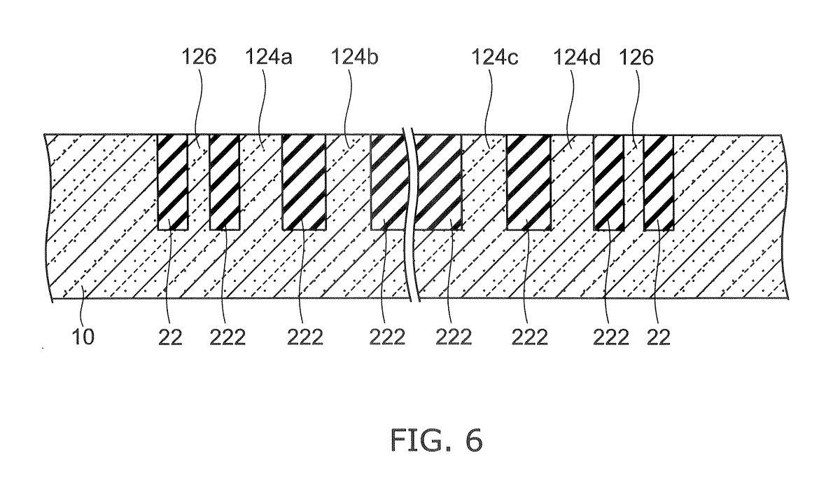

(B) An insulating film of phosphosilicate glass (PSG) is deposited on the substrate 10 by chemical vapor deposition (CVD) so as to bury the first and second gap 120, 122. As shown in FIG. 6, the deposited insulating film is planarized by CMP so as to expose the surface of the substrate 10, thereby forming a sacrificial film 222 buried in the first gap 120 and a sidewall film 22 buried in the second gap 122.

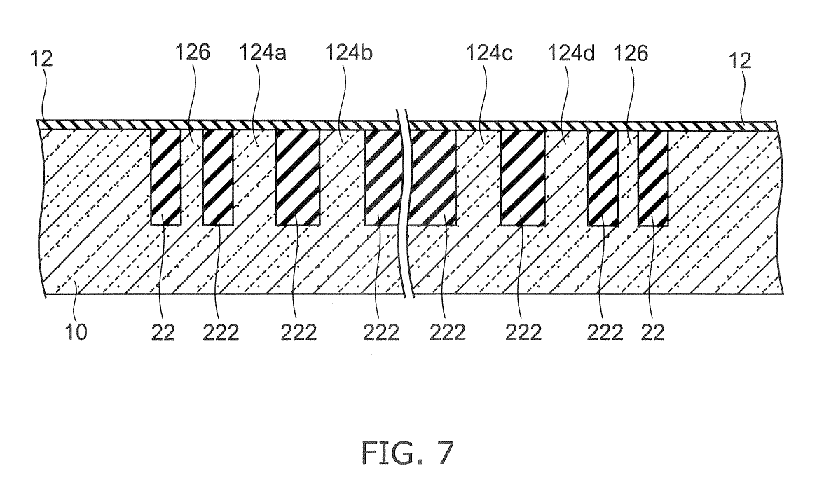

(C) As shown in FIG. 7, a protection film 12 of AlN is deposited by sputtering on the surface of the substrate 10 with the sacrificial film 222 and the sidewall film 22 buried therein.

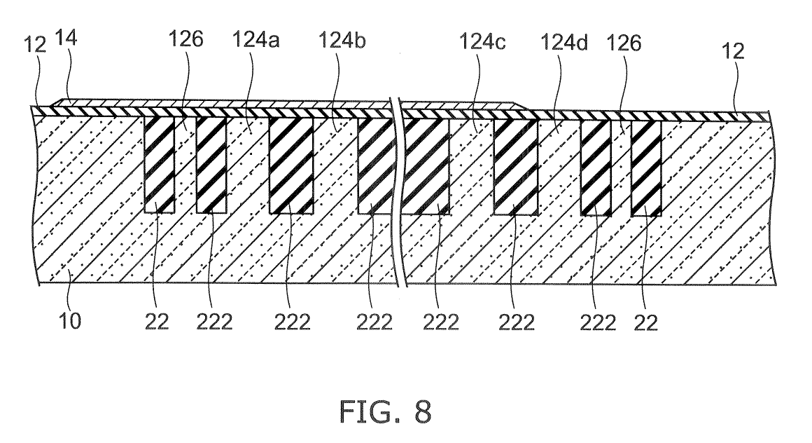

(D) As shown in FIG. 8, a lower electrode 14 of AlTa/Al extending above the sacrificial film 222 and the first supports 124a-124c from above the substrate 10 is formed by sputtering, photolithography, and RIE. The photolithography condition is adjusted to bevel the end of the resist mask, thereby beveling the end of the lower electrode 14.

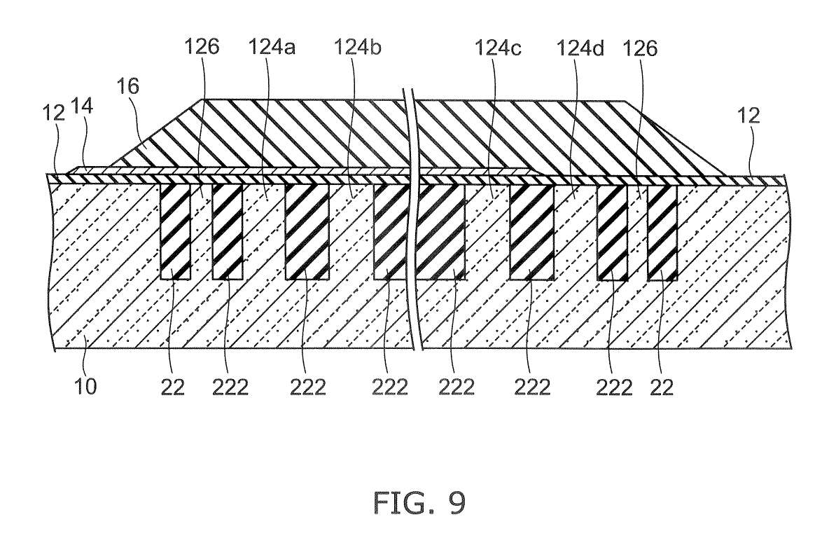

(E) As shown in FIG. 9, a piezoelectric film 16 of AlN is formed by sputtering, photolithography, and RIE. Note that the AlN piezoelectric can alternatively be etched by wet etching with alkali solution.

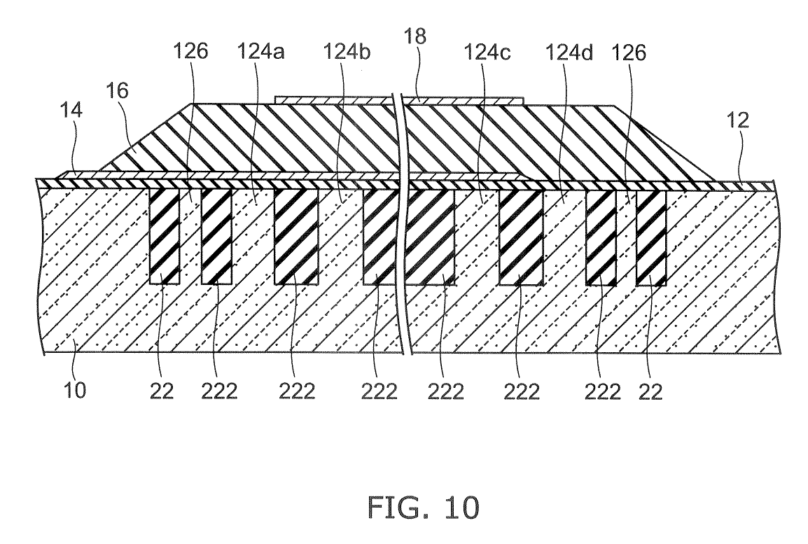

(F) As shown in FIG. 10, an upper electrode 18 of Mo is formed by sputtering, photolithography, and wet etching.

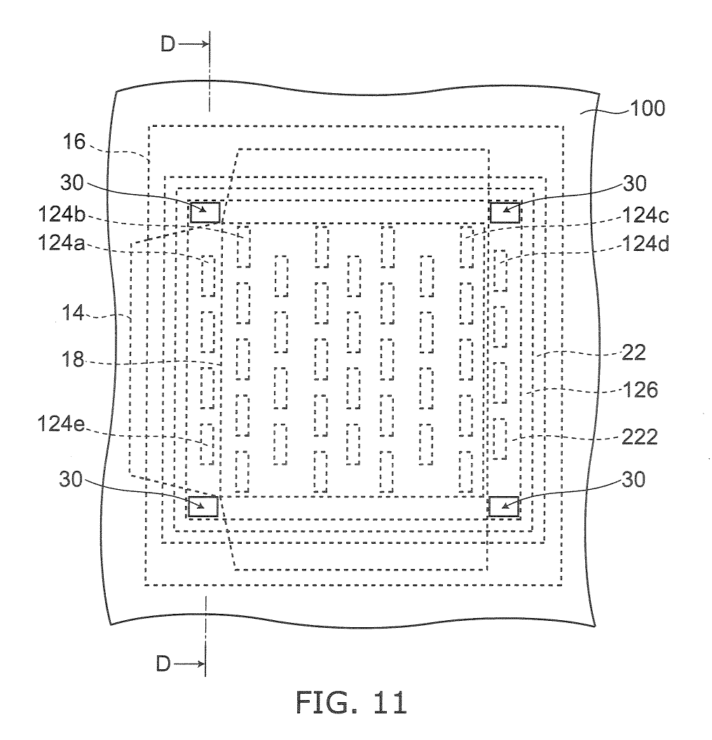

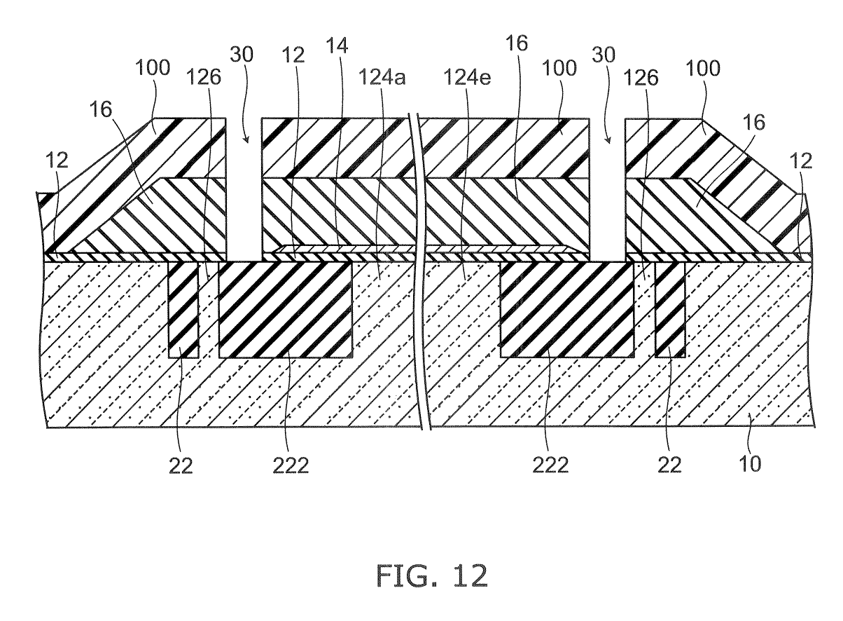

(G) As shown in FIGS. 11 and 12, a resist film 100 is used as a mask to selectively remove the piezoelectric film 16 and the protection film 12 by photolithography and RIE, thereby forming openings 30. The surface of the sacrificial film 222 is exposed in the openings 30. Four openings 30 are located near the corner of the rectangular second support 126, but the location and the number of the openings are not limited thereto. For example, the openings can be located anywhere except the region where the upper and lower electrode 14, 18 are opposed to each other. The number of openings may be one or more than one. If the lower and upper electrode 14, 18 are made of a material having resistance (to corrosion) against etchants used in etching away at least part of the sacrificial film 222 and the first and second support(s) 124a-124d, 126, then openings passing through the lower and upper electrode 14, 18 as well as through the piezoelectric film 16 and the protection film 12 can be provided in the region where the lower and upper electrode 14, 18 are opposed to each other.

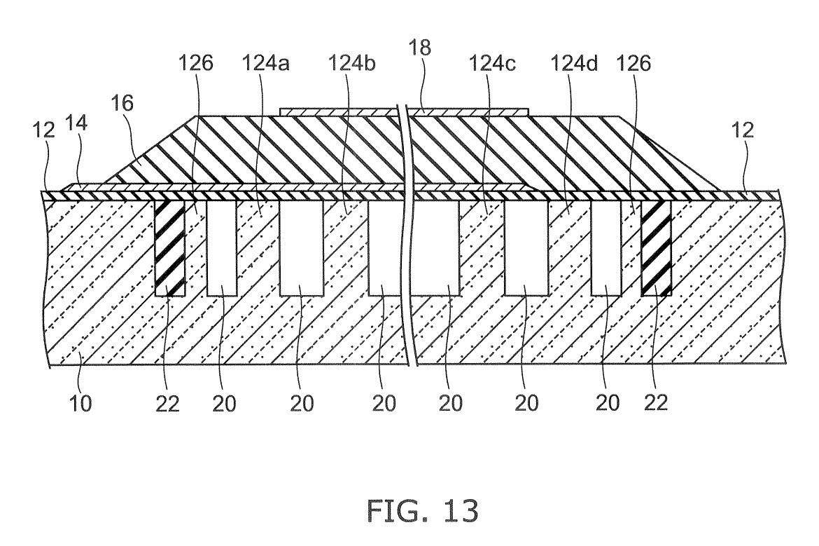

(H) As shown in FIG. 13, the sacrificial film 222 below the lower electrode 14 and the piezoelectric film 16 is selectively removed through the openings 30 by wet etching with buffered hydrofluoric acid (BHF), thereby forming a cavity 20. The sidewall film 22 is covered with the second support 126 of Si and is not exposed to the BHF or other wet etching solution. Thus the sidewall film 22 is not removed, and subsequently serves as an etch stop film in the in-plane direction of the substrate 10 when at least part of the first and second support(s) 124a-124d, 126 is etched away. The lower electrode 14 and the piezoelectric film 16 are supported at the surface level of the substrate 10 by the first and second support(s) 124a-124d, 126 below the protection film 12.

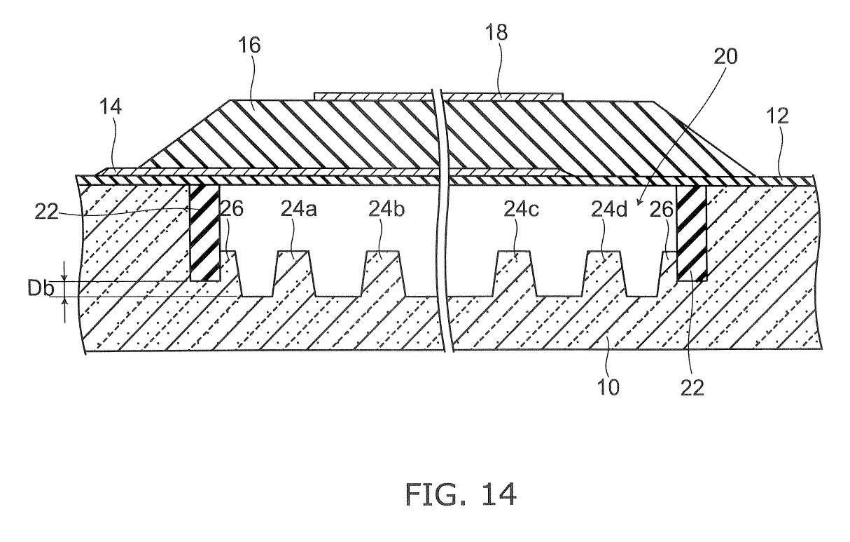

(I) The first and second support(s) 124a-124d, 126 below the protection film 12 are each selectively removed in part of the height through the openings 30 and the cavity 20 by chemical dry etching (CDE) with Freon (CF₄) and oxygen (O₂). If the first and second support(s) 124a-124d, 126 are thinned at the upper portion along the depth as shown in FIG. 5B, they are processed so as to be easily removed from the upper portion. While the first and second support(s) 124a-124d, 126 are removed by CDE, the bottom surface of the cavity 20 is dug down to a depth of Db relative to the sidewall film 22. As a result, as shown in FIG. 14, protrusions 24a-24d and a surrounding wall 26 having tops lower than the horizontal level of the upper surface of the substrate 10 are formed on the bottom surface of the cavity 20 below the lower electrode 14. Note that in CDE with CF₄ and O₂, the PSG sidewall film 22 and the AlN protection film 12 are not etched. Thus an FBAR shown in FIGS. 1 to 3 is manufactured.

In the method of manufacturing an FBAR according to the embodiment, the spacing between each pair of the plurality of first supports 124a-124e is about 10 μm or less. Therefore dishing that may occur in the surface of the sacrificial film 222 can be prevented even if the sacrificial film 222 is planarized by CMP. As a result, the strain in the resonator section 40 can be reduced.

Even after the sacrificial film 222 is removed, the lower electrode 14 and the piezoelectric film 16 are supported by the first supports 124a-124e. Therefore the lower electrode 14 and the piezoelectric film 16 do not bend toward the bottom of the cavity 20.

Furthermore, when the first and second support(s) 124a-124e, 126 below the protection film 12 are removed by CDE, a plurality of protrusions 24a-24e are formed on the bottom surface of the cavity 20. The area of the upper surface of the plurality of protrusions 24a-24e is less than the total area of the resonator section 40. Therefore, if the resonator section 40 bends during the water washing or other manufacturing process and comes into contact with the upper surface of the plurality of protrusions 24a-24e, the resonator section 40 is not stuck to the upper surface of the plurality of protrusions 24a-24e.

Thus the embodiment can prevent the resonator section 40 from being subjected to strain and being stuck to the substrate 10. As a result, an FBAR can be manufactured without the degradation of resonance characteristics.

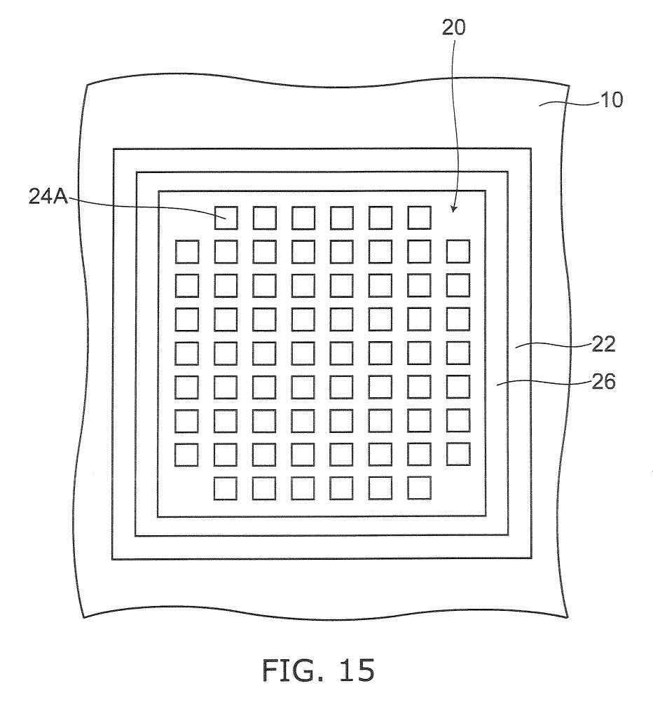

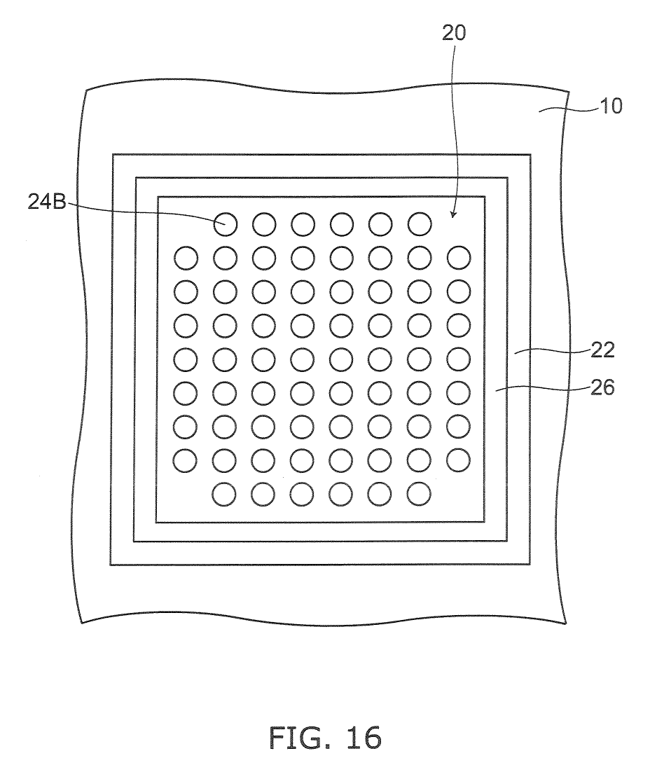

The embodiment is based on a plurality of protrusions 24a-24e having a rectangular planar shape However, the planar shape of the plurality of protrusions is not limited thereto. For example, as shown in FIG. 15, it is possible to use a plurality of square protrusions 24A, each measuring about 1 μm to about 10 μm per side. Alternatively, as shown in FIG. 16, it is possible to use a plurality of circular protrusions 24B, each having a diameter of about 1 μm to about 10 μm. Note that in FIGS. 15 and 16, for simplicity, the protection film and the resonator section are omitted. Here the spacing between the adjacent protrusions 24A or 24B can be set appropriately under the condition that dishing can be prevented during CMP for burying the sacrificial film 222. For example, the spacing is set to about 10 μm or less as in the case of the protrusions 24a-24e.

### First Variation

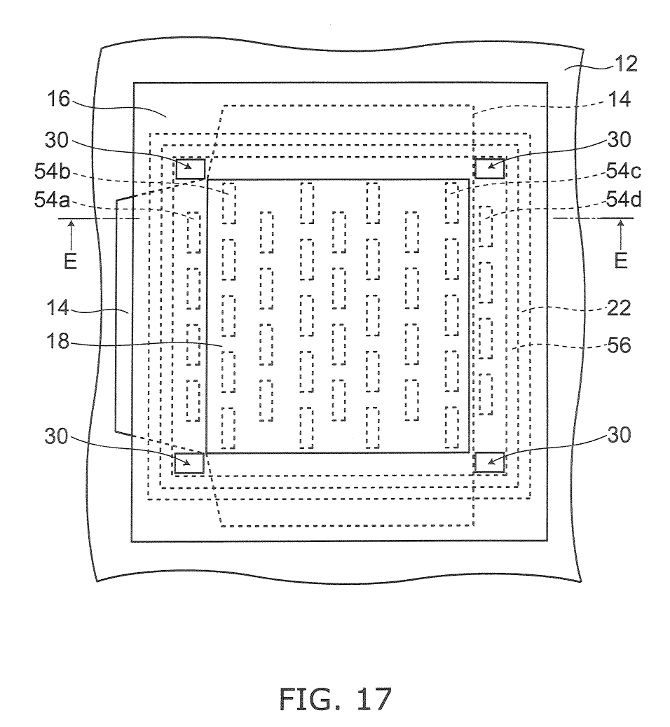

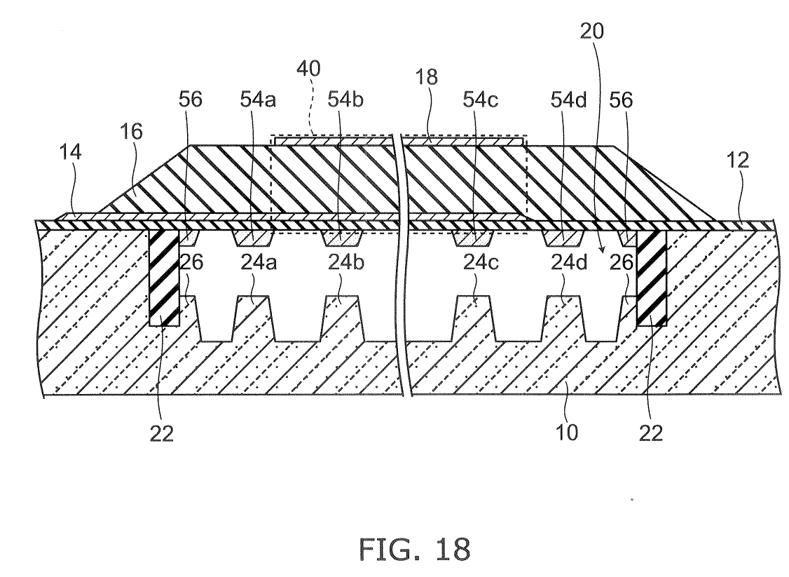

As shown in FIGS. 17 and 18, an FBAR according to a first variation of the embodiment of the invention further includes a plurality of protrusions also serving as first additional films 54a, 54b, 54c, 54d, . . . and a surrounding film 56 on the lower surface of the protection film 12 facing the cavity 20. The plurality of first additional films 54a-54d, . . . are opposed to the plurality of protrusions 24a-24d, . . . provided in the substrate 10 defining the bottom surface of the cavity 20. The surrounding film 56 is opposed to the surrounding wall 26 and in contact with the sidewall film 22. The first additional films 54a, 54b, 54c, 54d, . . . and the surrounding film 56 may be formed from the same material as the substrate 10.

Among the plurality of first additional films 54a-54d, the first additional films 54b, 54c, . . . are located below the lower electrode 14 in the resonator section 40. The resonance frequency of the FBAR is approximately in inverse proportion to the square root of the mass of the lower and upper electrode 14, 18 and the like provided on the piezoelectric film 16. Therefore the resonance frequency of the resonator section 40 can be varied by the mass addition effect of the first additional films 54b, 54c, . . . in the resonator section 40.

The first variation of the embodiment is different from the embodiment in that a plurality of first additional films 54a-54d and a surrounding film 56 are provided on the lower surface of the protection film 12 facing the cavity 20. The other configuration is the same as the embodiment, and the duplicated description is omitted.

In the first variation of the embodiment, as shown in FIG. 13, a cavity 20 is formed below the lower electrode 14 and the piezoelectric film 16. The first and second support(s) 124a-124d, 126 below the protection film 12 are selectively removed through the cavity 20 by CDE with CF₄ and O₂. The first and second support(s) 124a-124d, 126 can be thinned at the center portion along the depth as shown in FIG. 5C. Thus, by controlling the CDE etching condition, as shown in FIG. 18, the center portion along the depth of the first and second support(s) 124a-124d, 126 can be removed to form a plurality of first additional films 54a-54d, . . . and a surrounding film 56 on the lower surface of the protection film 12 facing the cavity 20. The etching amount of the plurality of first additional films 54a-54d can be controlled to adjust the resonance frequency of the resonator section 40.

In the first variation of the embodiment, protrusions serving as a plurality of first additional films 54a-54d are formed on the lower surface of the protection film 12, and a plurality of protrusions 24a-24e are formed on the bottom surface of the cavity 20. Therefore, if the resonator section 40 bends during the water washing or other manufacturing process and the lower surface of the plurality of first additional films 54a-54d comes into contact with the upper surface of the plurality of protrusions 24a-24e, the plurality of first additional films 54a-54d are not stuck to the upper surface of the plurality of protrusions 24a-24e. Thus the first variation of the embodiment can prevent the resonator section 40 from being stuck to the substrate 10. As a result, the degradation of resonance characteristics of the FBAR can be prevented. In addition, in the first variation of the embodiment, the area of the lower surface of the protrusions serving as a plurality of first additional films 54a-54d is less than the total area of the resonator section 40. Therefore the resonator section 40 can be prevented from being stuck to the substrate 10 even if a plurality of protrusions 24a-24e are not formed on the bottom surface of the cavity 20.

### Second Variation

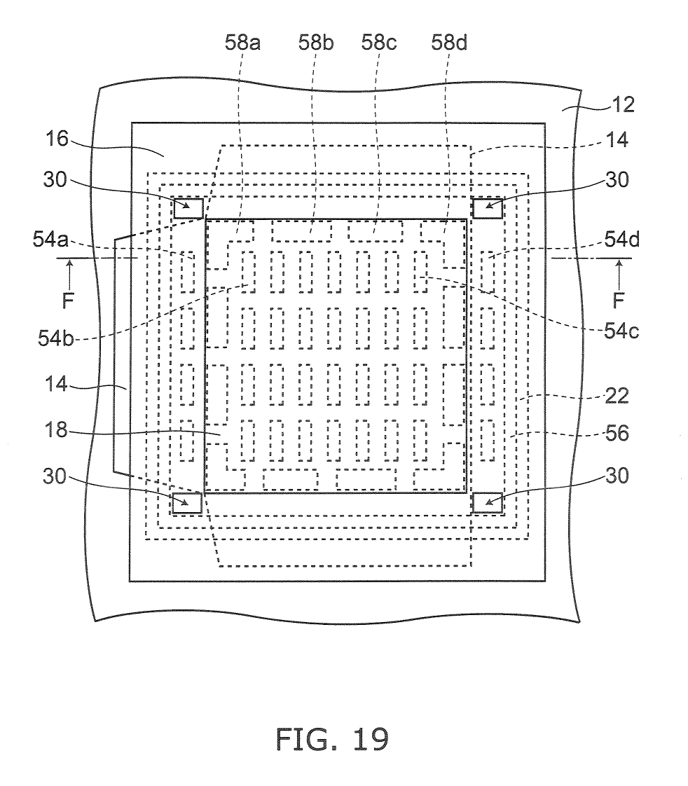

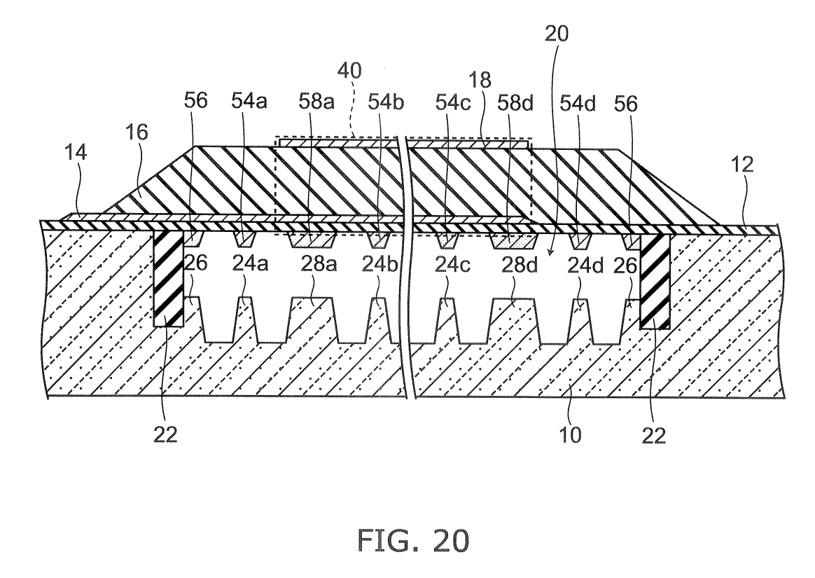

As shown in FIGS. 19 and 20, an FBAR according to a second variation of the embodiment of the invention further includes a plurality of protrusions also serving as second additional films 58a, 58b, 58c, 58d, . . . on the lower surface of the protection film 12 facing the cavity 20. The plurality of second additional films 58a-58d, . . . are located below the lower electrode 14 in the resonator section 40 along the inside of the periphery of the resonator section 40. The plurality of second additional films 58a-58d, . . . are opposed to the plurality of protrusions 24a-24d, . . . provided on the bottom surface of the cavity 20. The plurality of second additional films 58a-58d, and the surrounding film 56 may be formed from the same material as the substrate 10.

Bulk acoustic waves, which carry high-frequency signals in the resonator section 40 of the FBAR, are longitudinal waves propagating between the opposed planes of the lower and upper electrode 14, 18. Besides longitudinal waves, transverse waves also occur in the resonator section 40. The transverse wave travels parallel to the interfaces that the lower and upper electrode 14, 18 make with the piezoelectric film 16. The transverse wave traveling in the resonator section 40 is reflected at the end of the resonator section 40. For example, a transverse wave traveling along one side of the resonator section 40 is reflected at the end of the resonator section 40 and travels in the opposite direction along the same path. This wave interferes with another transverse wave reflected at the opposite end, thereby generating spurious modes.

In the second variation of the embodiment, the second additional films 58a-58d, . . . located along the inside of the periphery of the resonator section 40 serve to attenuate transverse waves at the end of the resonator section 40. As a result, the generation of spurious modes can be prevented. Preferably, at least one side of the second additional films 58a-58d, is larger than the side of the first additional films 54a-54d, in the range of about 5 μm to about 30 μm, for example. Then, even if the first additional films 54a-54d, . . . are etched off for adjusting the resonance frequency, the second additional films 58a-58d, . . . can be left.

The second variation of the embodiment is different from the embodiment in that a plurality of second additional films 58a-58d, . . . are provided on the lower surface of the protection film 12 facing the cavity 20 along the inside of the periphery of the resonator section 40. The other configuration is the same as the embodiment, and the duplicated description is omitted.

In the second variation of the embodiment, protrusions serving as a plurality of first additional films 54a-54d and second additional films 58a-58d are formed on the lower surface of the protection film 12, and a plurality of protrusions 24a-24e, 28a-28d are formed on the bottom surface of the cavity 20 Therefore, if the resonator section 40 bends during the water washing or other manufacturing process and the lower surface of the plurality of first additional films 54a-54d and the plurality of second additional films 58a-58d comes into contact with the upper surface of the plurality of protrusions 24a-24e, 28a-28d, the plurality of first additional films 54a-54d and the plurality of second additional films 58a-58d are not stuck to the upper surface of the plurality of protrusions 24a-24e, 28a-28d. Thus the second variation of the embodiment can prevent the resonator section 40 from being stuck to the substrate 10. As a result, the degradation of resonance characteristics of the FBAR can be prevented. In addition, in this variation again, the area of the lower surface of the protrusions serving as a plurality of first additional films 54a-54d and second additional films 58a-58d is less than the total area of the resonator section 40. Therefore the resonator section 40 can be prevented from being stuck to the substrate 10 even if a plurality of protrusions 24a-24e, 28a-28d are not formed on the bottom surface of the cavity 20.

### Other Embodiments

The embodiment of the invention has been described above. However, the description and the drawings, which constitute part of this disclosure, are not to be understood as limiting the scope of the invention. Various alternative embodiments, examples, and practical applications will be apparent to those skilled in the art from this disclosure.

In the embodiment and the first and second variation of the invention, a sidewall film 22 is provided on the side surface of the cavity 20 The sidewall film 22 serves as an etch stop film in CDE for removing the first and second support(s) 124a-124e, 126. However, the sidewall film may be omitted if the cavity 20 does not extend beyond the periphery of the lower electrode 14 and the piezoelectric film 16 provided on the surface of the substrate 10 when the first and second support(s) 124a-124e, 126 are removed In the embodiment, a plurality of protrusions 24a-24e are provided on the substrate 10 defining the bottom surface of the cavity 20. However, the surface having a plurality of protrusions is not limited to the bottom surface of the cavity 20. The role of the plurality of protrusions may be played by at least either of the plurality of first additional films 54a-54d, or the plurality of second additional films 58a-58d, . . . , which are provided on the lower surface of the protection film 12 formed in the cavity 20 on the resonator section 40 side.

For example, a silicon-on-insulator (SOI) substrate is used to form first and second support(s) in a semiconductor layer on a buried oxide film (BOX). Then a material having a certain etching selection ratio relative to the BOX is buried as a sacrificial film. The first and second support(s) can be processed so that the width is smaller on the BOX side than on the surface side of the semiconductor layer by adjusting the condition for RIE or other etching process. The sacrificial film is selectively etched away to form a cavity. Then part of the first and second support(s) below the protection film is each selectively removed through the cavity by CDE. As a result, no protrusion remains on the BOX defining the bottom surface of the cavity, and a plurality of protrusions are formed on the lower surface of the protection film defining the upper surface of the cavity. The plurality of protrusions provided on the lower surface of the protection film serve to prevent the resonator section from being stuck to the bottom surface of the cavity.

Thus, it is to be understood that the invention encompasses various embodiments that are not described herein. Therefore the scope of the invention is defined only by the appended claims, which are to be interpreted in light of the above description.

1. A film bulk acoustic resonator comprising:
a substrate having a cavity in a surface thereof;
a lower electrode extending above the cavity from an upper surface of the substrate;
a piezoelectric film provided on the lower electrode;
an upper electrode opposed to the lower electrode and provided on the piezoelectric film; and
a plurality of protrusions provided below the lower electrode in the cavity.

2. The film bulk acoustic resonator according to claim 1, further comprising a sidewall film surrounding the plurality of protrusions, the sidewall film being made of a material different from that of the substrate.

3. The film bulk acoustic resonator according to claim 2, further comprising a surrounding wall provided on a side of the substrate defining a bottom surface of the cavity, the surrounding wall touching the sidewall film.

4. The film bulk acoustic resonator according to claim 3, further comprising a surrounding film opposed to the surrounding wall, the surrounding film touching the sidewall film.

5. The film bulk acoustic resonator according to claim 4, wherein the surrounding film is made of the same material as the substrate.

6. The film bulk acoustic resonator according to claim 1, wherein the plurality of protrusions are provided in the cavity on a side of the substrate defining a bottom surface of the cavity.

7. The film bulk acoustic resonator according to claim 1, wherein the plurality of protrusions are provided in the cavity on a side of a resonator section defined by a region formed above the cavity where the lower electrode is opposed to the upper electrode.

8. The film bulk acoustic resonator according to claim 7, wherein the plurality of protrusions are made of the same material as the substrate.

9. The film bulk acoustic resonator according to claim 7, wherein the plurality of protrusions are provided at least along the inside of the periphery of the resonator section in the cavity on the side of the resonator section.

10. The film bulk acoustic resonator according to claim 1, wherein a total area of top surfaces of the protrusions is less than an area of a resonator section defined by a region formed above the cavity where the lower electrode is opposed to the upper electrode.

11. The film bulk acoustic resonator according to claim 7, wherein a total area of lower surfaces of the protrusions is less than an area of the resonator section.

12. The film bulk acoustic resonator according to claim 1, further comprising a protection film provided between the cavity and the lower electrode, wherein an end of the lower electrode is beveled at an angle smaller than a right angle with respect to a surface of the protection film.

13. The film bulk acoustic resonator according to claim 1, wherein some of the plurality of protrusions are provided in the cavity on a side of the substrate defining a bottom surface of the cavity, and other of the plurality of protrusions are provided in the cavity on a side of a resonator section defined by a region formed above the cavity where the lower electrode is opposed to the upper electrode, the some of the plurality of protrusions and the other of the plurality of protrusions oppose each other.

14. A method of manufacturing a film bulk acoustic resonator comprising:
removing part of a substrate to form a plurality of isolated first supports and a second support surrounding the plurality of first supports in a box configuration;
forming a sacrificial film and a sidewall film so as to bury, respectively, a first gap provided between each pair of the plurality of first supports and between the plurality of first supports and the second support and a second gap provided around the second support between the second support and the substrate;
forming a lower electrode extending above the sacrificial film and the first supports from above the substrate;
forming a piezoelectric film on a surface of the lower electrode;
forming an upper electrode opposed to the lower electrode and located on the piezoelectric film;
removing the sacrificial film to form a cavity below a resonator section defined by a region where the lower electrode is opposed to the upper electrode; and
removing at least part in a height direction of each of the plurality of first supports in the cavity.

15. The method of manufacturing a film bulk acoustic resonator according to claim 14, wherein the first supports are formed so that an upper portion along the height direction is thinned.

16. The method of manufacturing a film bulk acoustic resonator according to claim 14, wherein the first supports are formed so that a center portion along the height direction is thinned.

17. The method of manufacturing a film bulk acoustic resonator according to claim 14, wherein an upper portion of the first supports are removed.

18. The method of manufacturing a film bulk acoustic resonator according to claim 14, wherein a center portion of the first supports are removed.

19. The method of manufacturing a film bulk acoustic resonator according to claim 14, further comprising forming a protection film extending above the sacrificial film and the first supports from above the substrate, before forming the lower electrode.

20. The method of manufacturing a film bulk acoustic resonator according to claim 14, wherein an end of the lower electrode is beveled at an angle smaller than a right angle with respect to a surface of the protection film.
